(19) United States
(12) Patent Application Publication
(10) Pub. No.: US 2014/0008657 A1
(43) Pub. Date: Jan. 9, 2014

(54) METHOD OF MANUFACTURING FLEXIBLE DISPLAY AND SUBSTRATE FOR MANUFACTURING FLEXIBLE DISPLAY

(71) Applicant: HISENSE HIVIEW TECH CO., LTD., QINGDAO CITY (CN)

(72) Inventors: LIN LU, QINGDAO CITY (CN); JIANWEI CAO, QINGDAO CITY (CN); WEIDONG LIU, QINGDAO CITY (CN)

(73) Assignee: HISENSE HIVIEW TECH CO., LTD., QINGDAO CITY (CN)

(21) Appl. No.: 13/732,257

(22) Filed: Dec. 31, 2012

(30) Foreign Application Priority Data
Jul. 5, 2012 (CN) 201210232494.7

(51) Int. Cl. H01L 33/16; H01L 33/48

(52) U.S. Cl. CPC H01L 33/16; H01L 33/48
USPC 257/59; 438/28; 257/72

(57) ABSTRACT

A method of manufacturing a flexible display includes forming a silicon sacrificial layer on a rigid base material layer, affixing a flexible base material layer to the silicon sacrificial layer by an adhesive layer, forming a display element layer on the flexible base material layer, and utilizing a fluorine-containing corrosive gas to etch and gasify the silicon sacrificial layer to cause the flexible base material layer to separate from the rigid base material layer. A substrate for manufacturing a flexible display includes a rigid base material layer, a silicon sacrificial layer disposed on the rigid base material layer, an adhesive layer disposed on the silicon sacrificial layer, a flexible base material layer disposed on the adhesive layer, and a display element layer disposed on flexible base material layer.

### CROSS-REFERENCE TO RELATED APPLICATIONS

This application claims the priority benefit of Chinese application No. 201210232494.7, filed on Jul. 5, 2012, titled with “method of manufacturing flexible display and substrate for manufacturing flexible display”. The entirety of the above-mentioned application are hereby incorporated by reference herein and made a part of this specification.

### TECHNICAL FIELD

The present invention relates to flexible displays, and particularly to a method of manufacturing a flexible display and a substrate for manufacturing a flexible display.

### BACKGROUND

Currently, many types of display technology can be applied in flexible display, including, for example, the traditional LCD technology, the bistable LCD technology, the OLED (organic light-emitting diode) display technology, the electrophoretic display technology, the electrochromic display technology, and the electroluminescent display technology. Compared with other flexible displays, FOLED (flexible organic light-emitting diode) display has more advantages, such as self-luminescence, fast response speed, high brightness, wide viewing angle, and low cost. Moreover, the FOLED display is based on the display of flexible organic materials, which can be curled, folded, or even as part of a wearable computer. Therefore, the FOLED display has a wide range of applications in portable products requiring good display effect and in special areas such as military field.

Traditional flexible display generally uses a flexible base material layer, for example, ultra-thin glass, stainless steel film, or a plastic substrate, with a thickness of less than 100 microns. Due to the fact that the flexible base material layer has the problems such as frangible, easy to get crinkled, and easy to deform, a rigid base material layer is generally required to affix together with the flexible base material layer in the actual manufacturing process to produce thin film transistor array and OLED on the flexible base material layer, and to package the thin film transistor array and the OLED. Finally, a suitable peeling method is used to peel the rigid base material layer off the flexible base material layer, to thereby finish the production of an FOLED display.

Accordingly, to properly affix the flexible base material layer with the rigid base material layer and peel the rigid base material layer off the flexible base material layer has become one of the key technologies in manufacturing a flexible display. The common method used to peel off the rigid base material layer includes laser irradiation method and water bath method. The laser irradiation method uses laser irradiation for heating the amorphous silicon film located between the flexible base material layer and the rigid base material layer, to cause the amorphous silicon film to become polycrystalline silicon to achieve the peeling. The water bath method uses water bath to cause a chemical reaction to the germanium oxide film located between the flexible base material layer and the rigid base material layer to achieve the peeling.

By continuous technological improvement, the above two peeling methods have improved the peeling effect to a certain extent in peeling the rigid base material layer off the flexible base material layer. However, by the above methods, the amorphous silicon film and the germanium oxide film cannot be completely and cleanly removed away, and the flexible base material layer is also easily subject to damage. Furthermore, process conditions in the above peeling methods are also difficult to control. As a result, the above peeling methods are ineffective in manufacturing high-quality flexible displays.

### SUMMARY

Therefore, the present invention provides a method of manufacturing a flexible display. The method includes forming a silicon sacrificial layer on a rigid base material layer, affixing a flexible base material layer to the silicon sacrificial layer by an adhesive layer, forming a display element layer on the flexible base material layer, and utilizing a fluorine-containing corrosive gas to etch and gasify the silicon sacrificial layer to cause the flexible base material layer to separate from the rigid base material layer.

The present invention further provides a substrate for manufacturing a flexible display. The substrate includes a rigid base material layer, a silicon sacrificial layer disposed on the rigid base material layer, an adhesive layer disposed on the silicon sacrificial layer, a flexible base material layer disposed on the adhesive layer, and a display element layer disposed on flexible base material layer. The silicon sacrificial layer is sandwiched between the rigid base material layer and the adhesive layer. The adhesive layer is sandwiched between the silicon sacrificial layer and the flexible base material layer. The flexible base material layer is sandwiched between the display element layer and the adhesive layer.

### BRIEF DESCRIPTION OF THE DRAWINGS

The present invention will become more readily apparent to those ordinarily skilled in the art after reviewing the following detailed description and accompanying drawings, in which:

FIGS. 1A to 1G show various steps of manufacturing a flexible display according a first embodiment of the present invention.

FIG. 2 is a schematic, top plan view of a substrate for manufacturing a plurality of flexible displays according to a second embodiment of the present invention.

FIG. 3 is a cross-sectional view of a single flexible display panel unit according to the second embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

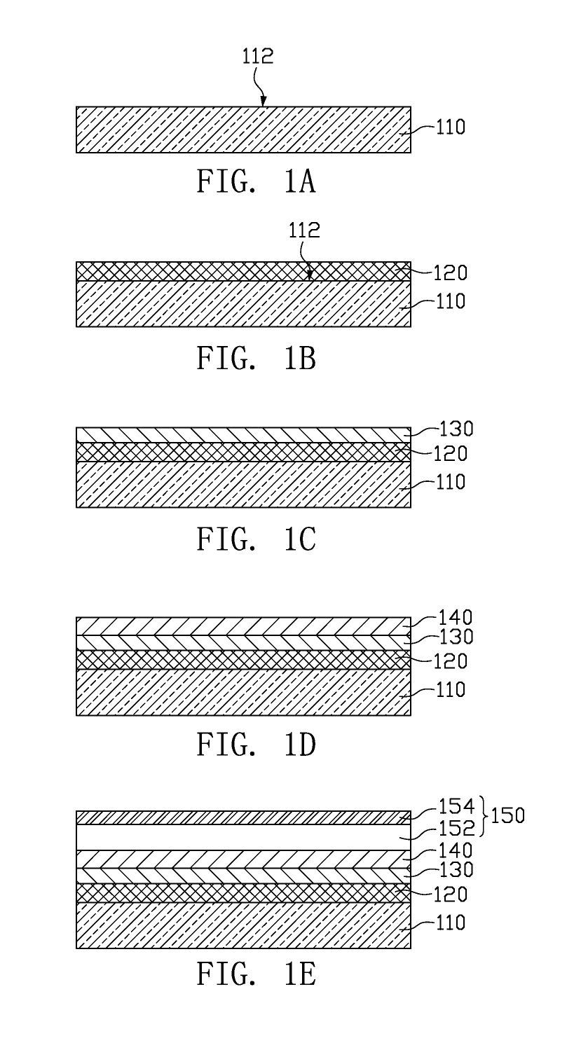

FIGS. 1A to 1G show various steps of manufacturing a flexible display according to a first embodiment of the present invention. Firstly, FIGS. 1A to 1E show various steps of manufacturing a substrate 100, which is thereafter used for manufacturing a flexible display. In this embodiment, taking FOLED (flexible organic light-emitting diode) display as an example, the substrate 100 is illustrated in an FOLED panel unit. In other words, the substrate 100 may be manufactured to ultimately form an independent flexible display, for example, an FOLED display.

Referring to FIG. 1A, a rigid base material layer 110 is firstly provided. In this embodiment, the rigid base material layer 110 is, such as, a quartz substrate or a glass substrate, but is not limited thereto. The rigid base material layer 110 is mainly to provide a support when circuits and display elements are produced on a flexible base material layer 140 in the following steps, so as to avoid crushing, wrinkles and deformation occurred on the flexible base material layer 140.

Referring to FIG. 1B, a silicon sacrificial layer 120 is formed on a top surface 112 of the rigid base material layer 110. A material of the silicon sacrificial layer 120 is, for example, amorphous silicon, monocrystalline silicon, or polycrystalline silicon. Preferably, the material of the silicon sacrificial layer 120 is, for example, amorphous silicon. The silicon sacrificial layer 120 can be formed by a PVD (physical vapor deposition) method or a CVD (chemical vapor deposition) method. A thickness of the silicon sacrificial layer 120 is, for example, 0.5 to 2 microns. In this embodiment, the silicon sacrificial layer 120 is, for example, an amorphous silicon layer formed by a sputtering method and having a thickness of about 1 micron.

Referring to FIG. 1C, an adhesive layer 130 is formed on the silicon sacrificial layer 120. A material of the adhesive layer 130 is, for example, a silica gel or an epoxy resin. The adhesive layer 130 can be formed, for example, by a spin coating method or a dispensing method. When the adhesive layer 130 is formed by a spin coating method, the adhesive layer 130 is preferably coated on the silicon sacrificial layer 120 uniformly. When the adhesive layer 130 is formed by a dispensing method, the adhesive layer 130 may include a plurality of scattered adhesive patterns, and the adhesive patterns are preferably distributed on the silicon sacrificial layer 120 uniformly.

Referring to FIG. 1D, a flexible base material layer 140 is affixed to the silicon sacrificial layer 120 by the adhesive layer 130. Specifically, the flexible base material layer 140 is firstly disposed on the adhesive layer 130, and the adhesive layer 130 is then cured so that the flexible base material layer 140 is firmly affixed to the silicon sacrificial layer 120 by the adhesive layer 130. Thus, through the adhesive layer 130, the flexible base material layer 140 is affixed to the rigid base material layer 110 on which the silicon sacrificial layer 120 is formed. The method for curing the adhesive layer 130 is not limiting, and can be based on the materials of the adhesive layer 130, for example, heat curing or UV (ultraviolet) curing. The flexible base material layer 140 is, for example, a glass film base material, a stainless steel film base material or a plastic base material, but is not limited thereto. A thickness of the flexible base material layer 140 is, for example, 5 to 200 microns. For example, the flexible base material layer 140 preferably has a thickness of about 80 microns. When the flexible base material layer 140 is a plastic base material, a water-oxygen blocking layer can be formed on the flexible base material layer 140 to effectively isolate the outside water and oxygen from the flexible base material layer 140. In addition, the adhesive layer 130 can also be formed on the flexible base material layer 140, and then the flexible base material layer 140 together with the adhesive layer 130 is adhered to the silicon sacrificial layer 120, so that the flexible base material layer 140 is affixed via the adhesive layer 130 to the rigid base material layer 110 on which the silicon sacrificial layer 120 is formed.

Referring to FIG. 1E, a display element layer 150 is formed on the flexible base material layer 140. Since the flexible base material layer 140 is bonded and supported on the rigid base material layer 110, when the display element layer 150 is formed on the flexible base material layer 140, the flexible base material layer 140 can effectively avoid crushing, wrinkles, and deformation occurred in forming the display element layer 150. In this embodiment, taking an FOLED display as an example, forming the display element layer 150 on the flexible base material layer 140 includes the following steps. Firstly, an organic light-emitting diode display layer 152 is formed on the flexible base material layer 140, and the organic light-emitting diode display layer 152 is then packaged to form a packaging layer 154 on the organic light-emitting diode display layer 152. The organic light-emitting diode display layer 152 includes thereon, for example, a thin film transistor control circuit, conductive electrodes, an organic material functional layer, and metal electrodes. Method of packaging the organic light-emitting diode display layer 152 includes, for example, a metal packaging method, a glass packaging method, a plastic packaging method, or a thin film packaging method, but is not limited thereto. Since elements of the organic light-emitting diode display layer 152 are seriously sensitive to water vapor and oxygen, the organic light-emitting diode display layer 152 should be isolated from water vapor and oxygen, or be produced under a vacuum environment in producing the organic light-emitting diode display layer 152. Forming the organic light-emitting diode display layer 152 and packaging the organic light-emitting diode display layer 154 are well known by skilled in the art and omitted here for clarity.

After the above-mentioned steps, the substrate 100 which can be thereafter used to manufacture a flexible display is finished. Referring to FIG. 1E, the substrate 100 for manufacturing a flexible display includes a rigid base material layer 110, a silicon sacrificial layer 120, an adhesive layer 130, a flexible base material layer 140, and a display element layer 150. The silicon sacrificial layer 120 is disposed on the top surface 112 of the rigid base material layer 110 and sandwiched between the adhesive layer 130 and the rigid base material layer 110. The adhesive layer 130 is disposed on the silicon sacrificial layer 120 and sandwiched between the silicon sacrificial layer 120 and the flexible base material layer 140. The flexible base material layer 140 is disposed on the adhesive layer 130 and sandwiched between the display element layer 150 and the adhesive layer 130. The display element layer 150 is disposed on the flexible base material layer 140. After the rigid base material layer 110 is peeled off, the substrate 100 is used for manufacturing a flexible display, as will be described in the following.

Referring to FIG. 1F, the silicon sacrificial layer 120 is etched by using a fluorine-containing corrosive gas 160 to gasify the silicon sacrificial layer 120, thereby separating the flexible base material layer 140 from the rigid base material layer 110. Specifically, the substrate 100 is put into a reaction apparatus filled with fluorine-containing corrosive gas at room temperature to undergo the peeling of the rigid base material layer 110. The fluorine-containing corrosive gas 160 is, for example, xenon fluoride (XeF₂), chlorine trifluoride (ClF₃), bromine trifluoride (BrF₃), or fluorine gas (F₂).

When xenon fluoride is selected as the fluorine-containing corrosive gas 160, a reaction apparatus is firstly provided and vacuumed to cause the reaction apparatus to have a vacuum pressure of less than 5 Torr, and then the xenon fluoride is filled into the reaction apparatus and used to etch the silicon sacrificial layer 120, wherein a pressure of the xenon fluoride in the reaction apparatus is less than 5 Torr. In the reaction apparatus filled with the xenon fluoride as the fluorine-containing corrosive gas, an isotropic chemical reaction is occurred between the silicon sacrificial layer 120 and the xenon fluoride, and the silicon sacrificial layer 120 is etched and gasified to turn into xenon gas and silicon tetrafluoride (SiF₄) gas to be capable of removing out of the reaction apparatus. When the silicon sacrificial layer 120 is etched for a specified time until the xenon fluoride filled into the reaction apparatus is almost fully reacted with the silicon sacrificial layer 120 to turn into xenon gas and silicon tetrafluoride gas, the xenon gas and the silicon tetrafluoride gas are removed out of the reaction apparatus and a reaction cycle is finished. Thereafter, a new amount of xenon fluoride is filled into the reaction apparatus to carry out another reaction cycle. Based on different sizes and thicknesses of the silicon sacrificial layer 120, reaction cycles and an etching time for each reaction cycle may be different and can be easily determined according to practical requirement. For example, about 1 to 1000 reaction cycles can be used, and an etching time for each reaction cycle is about 1 to 180 seconds, until the silicon sacrificial layer 120 is fully reacted with the xenon fluoride. After a full reaction between the silicon sacrificial layer 120 and the xenon fluoride, the silicon sacrificial layer 120 is wholly and cleanly removed away, and the rigid base material layer 110 is thus automatically and completely peeled off from the flexible base material layer 140. In the course of the chemical reaction between the silicon sacrificial layer 120 and the xenon fluoride, the silicon sacrificial layer 120 is cleanly and completely removed away with no residue, and also no extraneous matter is incurred, to thereby effectively peel the rigid base material layer 110 off from the flexible base material layer 140. The chemical reaction between the xenon fluoride and the silicon sacrificial layer 120 nearly does not cause any damage to the flexible base material layer 140 and the display element layer 150, and thus the performance of the flexible base material layer 140 and the display element layer 150 is effectively not influenced after the rigid base material layer 110 is peeled off. In particular, in peeling off the rigid base material layer 110, the electrical properties of each element, such as, the thin film transistor control circuit, the conductive electrodes, the organic material functional layer and the metal electrodes, of the display element layer 150 are not affected, to thereby facilitate manufacturing of high-quality flexible displays by using the substrate 100.

It is mentioned that, if chlorine trifluoride (ClF₃), bromine trifluoride (BrF₃), or fluorine gas (F₂) is used as the fluorine-containing corrosive gas 160, the reaction products between the silicon sacrificial layer 120 and the fluorine-containing corrosive gas 160 are still gases, for example, chlorine gas (or bromine gas) and silicon tetrafluoride (SiF₄) gas, which are also capable of removing out of the reaction apparatus.

When chlorine trifluoride is selected as the fluorine-containing corrosive gas 160, a reaction apparatus is firstly provided and vacuumed to cause the reaction apparatus to have a vacuum pressure of less than 5 Torr, and then the chlorine trifluoride is filled into the reaction apparatus and used to etch the silicon sacrificial layer 120, wherein a pressure of the chlorine trifluoride in the reaction apparatus is less than 5 Torr. In the reaction apparatus filled with the chlorine trifluoride as the fluorine-containing corrosive gas, an isotropic chemical reaction is occurred between the silicon sacrificial layer 120 and the chlorine trifluoride, and the silicon sacrificial layer 120 is etched and gasified to turn into chlorine gas and silicon tetrafluoride (SiF₄) gas to be capable of removing out of the reaction apparatus. When the silicon sacrificial layer 120 is etched for a specified time until the chlorine trifluoride filled into the reaction apparatus is almost fully reacted with the silicon sacrificial layer 120 to turn into chlorine gas and silicon tetrafluoride gas, the chlorine gas and the silicon tetrafluoride gas are removed out of the reaction apparatus and a reaction cycle is finished. Thereafter, a new amount of chlorine trifluoride is filled into the reaction apparatus to carry out another reaction cycle. Based on different sizes and thicknesses of the silicon sacrificial layer 120, reaction cycles and an etching time for each reaction cycle may be different and can be easily determined according to practical requirement. For example, about 1 to 1000 reaction cycles can be used, and an etching time for each reaction cycle is about 1 to 180 seconds, until the silicon sacrificial layer 120 is fully reacted with the chlorine trifluoride. After a full reaction between the silicon sacrificial layer 120 and the chlorine trifluoride, the silicon sacrificial layer 120 is wholly and cleanly removed away, and the rigid base material layer 110 is thus automatically and completely peeled off from the flexible base material layer 140.

When bromine trifluoride is selected as the fluorine-containing corrosive gas 160, a reaction apparatus is firstly provided and vacuumed to cause the reaction apparatus to have a vacuum pressure of less than 5 Torr, and then the bromine trifluoride is filled into the reaction apparatus and used to etch the silicon sacrificial layer 120, wherein a pressure of the bromine trifluoride in the reaction apparatus is less than 5 Torr. In the reaction apparatus filled with the bromine trifluoride as the fluorine-containing corrosive gas, an isotropic chemical reaction is occurred between the silicon sacrificial layer 120 and the bromine trifluoride, and the silicon sacrificial layer 120 is etched and gasified to turn into bromine gas and silicon tetrafluoride (SiF₄) gas to be capable of removing out of the reaction apparatus. When the silicon sacrificial layer 120 is etched for a specified time until the bromine trifluoride filled into the reaction apparatus is almost fully reacted with the silicon sacrificial layer 120 to turn into bromine gas and silicon tetrafluoride gas, the bromine gas and the silicon tetrafluoride gas are removed out of the reaction apparatus and a reaction cycle is finished. Thereafter, a new amount of bromine trifluoride is filled into the reaction apparatus to carry out another reaction cycle. Based on different sizes and thicknesses of the silicon sacrificial layer 120, reaction cycles and an etching time for each reaction cycle may be different and can be easily determined according to practical requirement. For example, about 1 to 1000 reaction cycles can be used, and an etching time for each reaction cycle is about 1 to 180 seconds, until the silicon sacrificial layer 120 is fully reacted with the bromine trifluoride. After a full reaction between the silicon sacrificial layer 120 and the bromine trifluoride, the silicon sacrificial layer 120 is wholly and cleanly removed away, and the rigid base material layer 110 is thus automatically and completely peeled off from the flexible base material layer 140.

When fluorine gas is selected as the fluorine-containing corrosive gas 160, a reaction apparatus is firstly provided and vacuumed to cause the reaction apparatus to have a vacuum pressure of less than 5 Torr, and then the fluorine gas is filled into the reaction apparatus and used to etch the silicon sacrificial layer 120, wherein a pressure of the fluorine gas in the reaction apparatus is less than 5 Torr. In the reaction apparatus filled with the fluorine gas as the fluorine-containing corrosive gas, an isotropic chemical reaction is occurred between the silicon sacrificial layer 120 and the fluorine gas, and the silicon sacrificial layer 120 is etched and gasified to turn into silicon tetrafluoride (SiF₄) gas to be capable of removing out of the reaction apparatus. When the silicon sacrificial layer 120 is etched for a specified time until the fluorine gas filled into the reaction apparatus is almost fully reacted with the silicon sacrificial layer 120 to turn into silicon tetrafluoride gas, the silicon tetrafluoride gas is removed out of the reaction apparatus and a reaction cycle is finished. Thereafter, a new amount of fluorine gas is filled into the reaction apparatus to carry out another reaction cycle. Based on different sizes and thicknesses of the silicon sacrificial layer 120, reaction cycles and an etching time for each reaction cycle may be different and can be easily determined according to practical requirement. For example, about 1 to 1000 reaction cycles can be used, and an etching time for each reaction cycle is about 1 to 180 seconds, until the silicon sacrificial layer 120 is fully reacted with the fluorine gas. After a full reaction between the silicon sacrificial layer 120 and the fluorine gas, the silicon sacrificial layer 120 is wholly and cleanly removed away, and the rigid base material layer 110 is thus automatically and completely peeled off from the flexible base material layer 140.

Referring to FIG. 1G, a certain amount of stress is possibly existed between the flexible base material layer 140 and the display element layer 150 which is disposed on the flexible base material layer 140. In peeling off the rigid base material layer 110 to obtain the substrate 100′, the substrate 100′ will become warped at a peripheral region thereof. Therefore, it is preferably to accelerate the isotropic chemical reaction between the silicon sacrificial layer 120 and the fluorine-containing corrosive gas 160, thereby accelerating the peeling speed of the rigid base material layer 110. After the rigid base material layer 110 is peeled off, the substrate 100′ is used for manufacturing a flexible display.

The method of the first embodiment is mainly used for manufacturing a single flexible display, for example, an FOLED display. In addition, the method is also applicable to simultaneously manufacture a plurality of flexible displays. In this situation, the substrate obtained by the method of the first embodiment will have a large area and can be used to manufacture a plurality of flexible displays. The following is described in detail based on a second embodiment of the present invention.

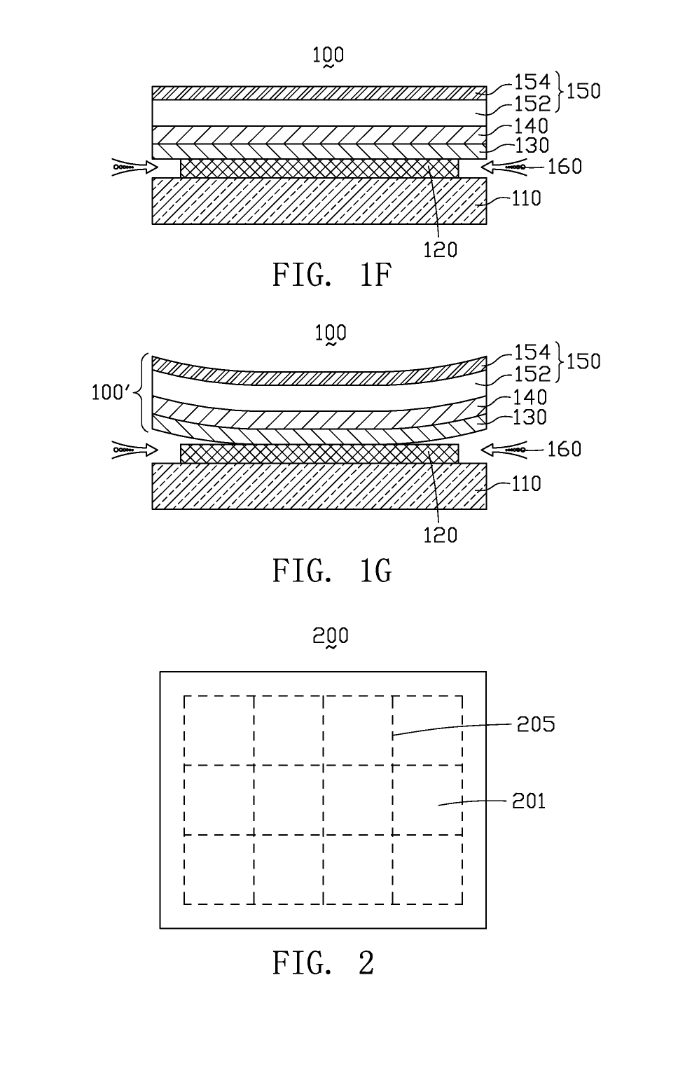

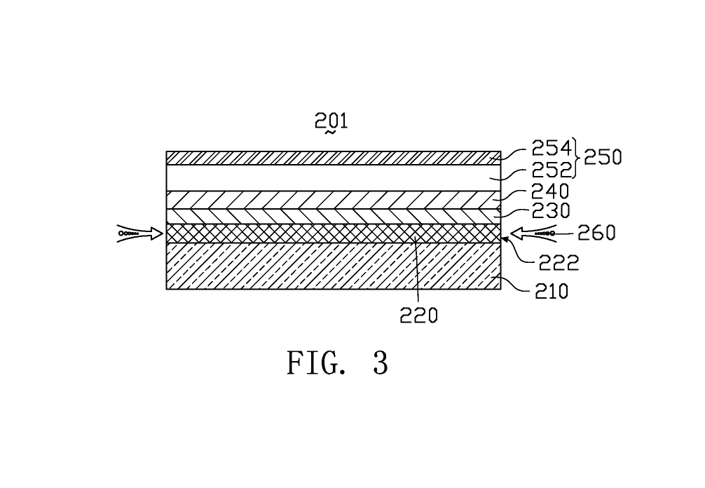

FIG. 2 is a schematic, top plan view of a substrate for manufacturing a plurality of flexible displays according to a second embodiment of the present invention. FIG. 3 is a cross-sectional view of a single flexible display panel unit according to the second embodiment of the present invention. Referring simultaneously to FIG. 2, FIG. 3 and the above first embodiment, the substrate 200 in this embodiment includes a silicon sacrificial layer 220, an adhesive layer 230, a flexible base material layer 240, and a display element layer 250 (including an organic light-emitting diode layer 252 and a packaging layer 254). The steps of this embodiment to form the silicon sacrificial layer 220, the adhesive layer 230, the flexible base material layer 240 and the display element layer 250 are similar to the steps of the first embodiment to form the silicon sacrificial layer 120, the adhesive layer 130, the flexible base material layer 140 and the display element layer 150 (including the organic light-emitting diode layer 152 and the packaging layer 154), and therefore are omitted here for clarity. Relative to the first embodiment, the substrate 200 of this embodiment has a larger size, and before the fluorine-containing corrosive gas 260 is utilized to etch the silicon sacrificial layer 220, a cutting step is needed to cut the substrate 200 into a plurality of flexible display panel units 201.

Specifically, referring to FIG. 2, in this embodiment, also taking FOLED display as an example, the substrate 200 includes a plurality of flexible display panel units 201, for example, FOLED panel units. That is, the substrate 200 may be used to manufacture a plurality of independent flexible displays, for example, FOLED displays. In this embodiment, the substrate 200 is defined by a number of cut lines 205 (the dashed line in FIG. 2), and by cutting the substrate 200 along the cut lines 205, a plurality of independent FOLED panel units 201 are obtained. Each FOLED panel unit 201 can be formed into an FOLED display.

In this embodiment, after the display element layer 250 is formed and before the rigid base material layer 210 is peeled off, a cutting step is required by using a cutting device (not shown) to cut the substrate 200 into plurality of independent FOLED panel units 201 along the cut lines 205 (the dashed line in FIG. 2). By the cutting step, the plurality of independent FOLED panel units 201 are separated from each other, and on the other hand, the side surfaces 222 of the silicon sacrificial layer 220 are exposed, so that the fluorine-containing corrosive gas 260 can react with the silicon sacrificial layer 220 rapidly starting from the side surfaces 222, thereby accelerating the peeling speed of the rigid base material layer 210.

It should be mentioned that, in the method of the first embodiment, the substrate 100 can also be carried out by a cutting step in order to accelerating the peeling speed of the rigid base material layer 110. For example, the substrate 100 can be cut around the peripheral edges thereof to expose the peripheral side surfaces of the silicon sacrificial layer 120, so that the fluorine-containing corrosive gas 160 can react rapidly starting from the peripheral side surfaces of the silicon sacrificial layer 120, to thereby accelerate the peeling speed of the rigid base material layer 110.

In summary, the method of manufacturing a flexible display uses fluorine-containing corrosive gas to react with the silicon sacrificial layer, so that the rigid base material layer is peeled off automatically and cleanly due to a gasification of the silicon sacrificial layer. Furthermore, the chemical reaction between of the fluorine-containing corrosive gas and the silicon sacrificial layer nearly does not cause any damage to the flexible base material layer and the display element layer, to thereby avoid causing adverse impact to the performance of the flexible base material layer and the display element layer in the course of peeling off the rigid base material layer. That is, the method of manufacturing a flexible display does not affect the electrical properties of elements, such as, the thin film transistor array and the organic material functional layer, of the display element layer in peeling off the rigid base material layer, thereby facilitating to produce high-quality flexible displays. Moreover, since a certain amount of stress is possibly existed between the flexible base material layer and the display element layer disposed on the flexible base material layer, a peripheral region of the substrate will become warped when the rigid base material layer is peeled off. It is preferably to accelerate the isotropic chemical reaction between the fluorine-containing corrosive gas and the silicon sacrificial layer to thereby accelerate the peeling speed of the rigid base material layer.

In addition, the method of manufacturing a flexible display is also applicable to manufacture a plurality of flexible displays, simultaneously. In this situation, the substrate made by the method will have a large area. After the display element layer is formed and before the rigid base material layer is peeled off, a cutting step is utilized to cut the substrate into a plurality of FOLED panel units. As a result, the plurality of FOLED panel units are separated from each other, and the peripheral side surfaces of the silicon sacrificial layer are exposed, so that the fluorine-containing corrosive gas can react with the silicon sacrificial layer rapidly starting from the peripheral side surfaces of the silicon sacrificial layer, thereby accelerating the peeling speed of the rigid base material layer.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method of manufacturing a flexible display, comprising:
forming a silicon sacrificial layer on a rigid base material layer;
affixing a flexible base material layer to the silicon sacrificial layer by an adhesive layer;
forming a display element layer on the flexible base material layer; and
utilizing a fluorine-containing corrosive gas to etch and gasify the silicon sacrificial layer to cause the flexible base material layer to separate from the rigid base material layer.

2. The method of manufacturing a flexible display according to claim 1, wherein a material of the silicon sacrificial layer is one of the followings: amorphous silicon, monocrystalline silicon and polycrystalline silicon.

3. The method of manufacturing a flexible display according to claim 2, wherein a thickness of the silicon sacrificial layer is in the range of 0.5 micron to 2 microns.

4. The method of manufacturing a flexible display according to claim 1, wherein the silicon sacrificial layer is formed by one of the followings: a sputtering method and a chemical vapor deposition method.

5. The method of manufacturing a flexible display according to claim 1, wherein prior to utilizing the fluorine-containing corrosive gas to etch and gasify the silicon sacrificial layer, a cutting step is utilized to expose a peripheral side surface of the silicon sacrificial layer.

6. The method of manufacturing a flexible display according to claim 1, wherein the fluorine-containing corrosive gas comprises at least one of the followings: xenon fluoride, chlorine trifluoride, bromine trifluoride and fluorine gas.

7. The method of manufacturing a flexible display according to claim 1, wherein in utilizing the fluorine-containing corrosive gas to etch and gasify the silicon sacrificial layer, a reaction apparatus is firstly provided and vacuumed, and then the fluorine-containing corrosive gas is filled into the reaction apparatus, a chemical reaction is occurred between the silicon sacrificial layer and the fluorine-containing corrosive gas, and the silicon sacrificial layer is etched and gasified to turn into gas to be capable of removing out of the reaction apparatus.

8. The method of manufacturing a flexible display according to claim 1, wherein forming the display element layer on the flexible base material layer comprises:
forming an organic light-emitting diode display layer on the flexible base material layer, wherein the organic light-emitting diode display layer comprises a thin film transistor control circuit, conductive electrodes, an organic material functional layer, and metal electrodes; and
packaging the organic light-emitting diode display layer to form a packaging layer.

9. The method of manufacturing a flexible display according to claim 8, wherein a method of packaging the organic light-emitting diode display layer comprises one of the followings: a metal packaging method, a glass packaging method, a plastic packaging method and a thin film packaging method.

10. A substrate for manufacturing a flexible display, comprising:
a rigid base material layer;
a silicon sacrificial layer disposed on the rigid base material layer;
an adhesive layer disposed on the silicon sacrificial layer, the silicon sacrificial layer being sandwiched between the rigid base material layer and the adhesive layer;
a flexible base material layer disposed on the adhesive layer, the adhesive layer being sandwiched between the silicon sacrificial layer and the flexible base material layer; and
a display element layer disposed on flexible base material layer, the flexible base material layer being sandwiched between the display element layer and the adhesive layer.

11. The substrate for manufacturing a flexible display according to claim 10, wherein a material of the silicon sacrificial layer is one of the followings: amorphous silicon, monocrystalline silicon and polycrystalline silicon.

12. The substrate for manufacturing a flexible display according to claim 11, wherein a thickness of the silicon sacrificial layer is in the range of 0.5 microns to 2 microns.

13. The substrate for manufacturing a flexible display according to claim 10, wherein the flexible base material layer is one of the followings: a glass film base material, a stainless steel film base material and a plastic base material.

14. The substrate for manufacturing a flexible display according to claim 13, wherein a thickness of the flexible base material layer is in the range of 5 to 200 microns.

15. The substrate for manufacturing a flexible display according to claim 10, wherein the display element layer comprises an organic light-emitting diode display layer and a packaging layer, the organic light-emitting diode display layer comprises a thin film transistor control circuit, conductive electrodes, an organic material functional layer and metal electrodes, and the packaging layer is one of the followings: a metal packaging layer, a glass packaging layer, a plastic packaging layer and a thin film packaging layer.

16. The substrate for manufacturing a flexible display according to claim 10, wherein the substrate comprises a plurality of flexible display panel units, and the flexible display panel units are separated from each other by cutting.

17. The substrate for manufacturing a flexible display according to claim 10, wherein the rigid base material layer is peeled off by utilizing a fluorine-containing corrosive gas to etch and gasify the silicon sacrificial layer when the substrate is used for manufacturing a flexible display.

18. The substrate for manufacturing a flexible display according to claim 17, wherein in utilizing the fluorine-containing corrosive gas to etch and gasify the silicon sacrificial layer, a reaction apparatus is firstly provided and vacuumed, and then the fluorine-containing corrosive gas is filled into the reaction apparatus, a chemical reaction is occurred between the silicon sacrificial layer and the fluorine-containing corrosive gas, and the silicon sacrificial layer is etched and gasified to turn into gas to be capable of removing out of the reaction apparatus.
